(19) United States
(12) Patent Application Publication
(10) Pub. No.: US 2020/0083155 A1
(43) Pub. Date: Mar. 12, 2020

(54) ELECTRICAL ROUTING COMPONENT LAYOUT FOR CROSSTALK REDUCTION

(71) Applicant: Intel Corporation, Santa Clara, CA (US)

(72) Inventors: Raul ENRIQUEZ SHIBAYAMA, Zapopan JAL (MX); Vijaya BODDU, Pleasanton, CA (US); Luis Nathan PEREZ ACOSTA, Tlaquepaque (MX); Francisco Javier GALARZA MEDINA, Tlaquepaque (MX); Kai XIAO, Portland, OR (US); Luis ROSALES-GALVAN, Portland, OR (US); Beom-Taek LEE, Beaverton, OR (US); Carlos Alberto LIZALDE MORENO, Guadalajara JAL (MX); Gaudencio HERNANDEZ SOSA, Guadalajara OU (MX); Mo LIU, Scotts Valley, CA (US)

(21) Appl. No.: 16/128,284

(22) Filed: Sep. 11, 2018

(51) Int. Cl. H01L 23/498; H05K 1/02; H05K 1/11

(52) U.S. Cl. CPC H01L 23/49838; H01L 23/49816; H05K 1/0245; H05K 1/114; H05K 2201/09236; H01L 2223/6616; H05K 2201/09409; H05K 2201/09609; H01L 2223/6638

(57) ABSTRACT

Apparatuses, systems and methods associated with electrical routing layout of printed circuit boards and integrated circuit substrates are disclosed herein. In embodiments, an apparatus includes a first electrically conductive path that extends through a region, wherein the first electrically conductive path includes a first pad located at a surface of the region, a first via that extends through the region, and a first trace that extends in a first direction. The apparatus further includes a second electrically conductive path that extends through the region, wherein the second electrically conductive path includes a second pad located at the surface and adjacent to the first pad, a second via that extends through the region, and a second trace that extends in a second direction. Other embodiments may be described and/or claimed.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

Legacy routing layouts for printed circuit boards and integrated circuit substrates were designed to conduct signals produced by legacy computer components. However, as the technology of computer components improved, the frequency of signals and the amount of transmissions within a period produced by the computer components increased. The legacy routing layouts were not designed for the increased frequency of signals and the increased amount of transmissions within a period.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates a top view of an example routing layout to be implemented by an electrical routing component, according to various embodiments.

FIG. 2 illustrates a perspective view of a portion of an example electrical routing component with example electrically conductive paths in accordance with the routing layout of FIG. 1, according to various embodiments.

FIG. 3 illustrates a top view of another example routing layout to be implemented by an electrical routing component, according to various embodiments.

FIG. 4 illustrates a chart showing example crosstalk measurement acting upon a differential signal in a routing layout, according to various embodiments.

FIG. 5 illustrates a portion of an example package, according to various embodiments.

FIG. 6 illustrates a crosstalk measurement of a first aggressor acting upon a victim, according to various embodiments.

FIG. 7 illustrates a crosstalk measurement of a second aggressor acting upon a victim, according to various embodiments.

FIG. 8 illustrates an example pad pattern that may be implemented by a computer component or an electrical routing component, according to various embodiments.

FIG. 9 illustrates another example pad pattern that may be implemented by a computer component or an electrical routing component, according to various embodiments.

FIG. 10 illustrates another example pad pattern that may be implemented by a computer component or an electrical routing component, according to various embodiments.

FIG. 11 illustrates a top view of an example routing pattern that may be implemented by an electrical routing component, according to various embodiments.

FIG. 12 illustrates an example computer device that may employ the apparatuses and/or methods described herein, in accordance with various embodiments.

### DETAILED DESCRIPTION

Apparatuses, systems and methods associated with electrical routing layout of printed circuit boards and integrated circuit substrates are disclosed herein. In embodiments, an apparatus includes a first electrically conductive path that extends through a region, wherein the first electrically conductive path includes a first pad located at a surface of the region, a first via that extends through the region, and a first trace that extends in a first direction. The apparatus further includes a second electrically conductive path that extends through the region, wherein the second electrically conductive path includes a second pad located at the surface and adjacent to the first pad, a second via that extends through the region, and a second trace that extends in a second direction.

In the following detailed description, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Aspects of the disclosure are disclosed in the accompanying description. Alternate embodiments of the present disclosure and their equivalents may be devised without parting from the spirit or scope of the present disclosure. It should be noted that like elements disclosed below are indicated by like reference numbers in the drawings.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

As used herein, the term “electrical routing component” refers to a printed circuit board (PCB) in some embodiments and to an integrated circuit (IC) substrate in other embodiments. It is to be understood that any of the features described as being implemented by an electrical routing component throughout this disclosure can be implemented in a PCB in some embodiments and can be implemented in an IC substrate in other embodiments.

As used herein, the term “electrically conductive path” refers to one or more electrically conductive elements (such as pads, traces, vias, electrically conductive regions, and/or electrically conductive layers) that form a continuous path through which electricity can be conducted.

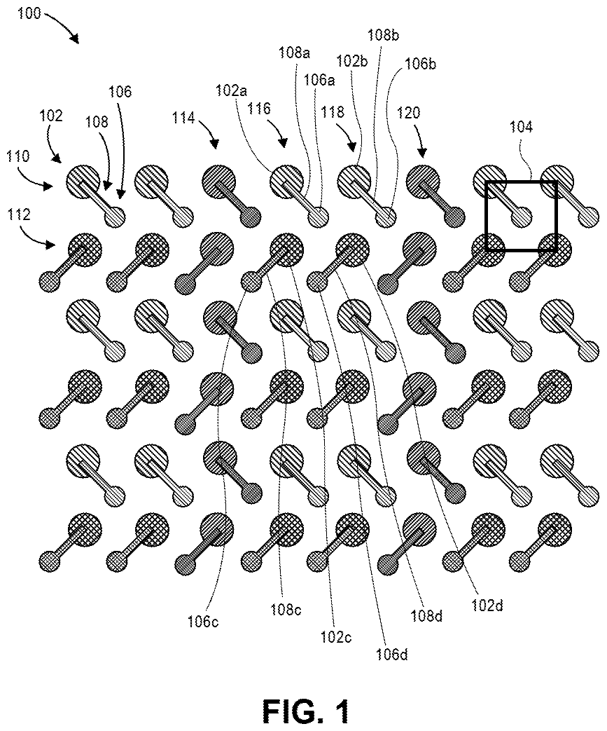

FIG. 1 illustrates a top view of an example routing layout 100 to be implemented by an electrical routing component, according to various embodiments. In particular, the routing layout 100 illustrates a plurality of electrically conductive paths, or portions thereof, that are to be implemented by an electrical routing component. Each of the electrically conductive paths can be coupled to a component that produces a signal or a ground for the electrical routing component, as described throughout. In the illustrated embodiment, each of the electrically conductive paths include a pad, a via, and a trace.

The routing layout 100 includes a plurality of pads 102. The pads 102 comprise electrically conductive elements to which a component (such as a processor, an integrated circuit substrate, and/or other computer hardware) can be mounted and to which leads of the component can be electrically coupled. For example, the pads 102 can form a ball grid array or a land grid array, or can comprise a plurality of plated holes to which the component may be mounted. The pads 102 are located at a surface of the electrical routing component. In other embodiments, the pads are located at a surface of a region or a layer of the electrical routing component. The pads 102 are arranged in a square pad pattern, where each group of four adjacent pads 102 form a square, such as square 104. The pads 102 located adjacent to each other may be referred to as being located in complementary positions. Accordingly, the pads 102 are arranged in a plurality of rows and columns.

The routing layout 100 further includes a plurality of vias 106. The vias 106 extend through a region of the electrical routing component. For example, the vias 106 extend through a layer of the electrical routing component in some embodiments. The vias 106 extend from the surface at which the pads 102 are located through the region to a surface at the opposite side of the region. A number of the vias 106 is equal to the number of pads 102, where each via 106 corresponds to one of the pads 102.

The routing layout 100 further includes a plurality of traces 108. Each of the traces 108 couple a pad 102 with a corresponding via 106. The traces 108 extend from the pad 102 to the corresponding via 106 along the surface where the pads 102 are located.

For brevity, the following description refers to a first row 110, a second row 112, a first column 114, a second column 116, a third column 118, and a fourth column 120 of the pads 102. It is to be understood that the features and/or arrangement described in relation to the first row 110, the second row 112, the first column 114, the second column 116, the third column 118, and the fourth column 120 are representative of the features and/or arrangements of other rows and columns of the pads 102 of the routing layout 100.

The second column 116 and the third column 118 of the pads 102 are to be utilized to conduct signals of differential pairs. The pads 102 within the second column 116 and the third column 118 that are within a same row are to be utilized to conduct a pair of signals corresponding to a single differential pair. For example, a first pad 102a located within the second column 116 and the first row 110 is to be utilized to conduct a first signal of a first differential pair, and a second pad 102b located within the third column 118 and the first row 110 is to be utilized to conduct a second signal of the first differential pair.

The pads 102 within the second column 116 and the third column 118 are to be utilized to conduct signals of a different differential pair from the pads 102 in an adjacent row. For example, the first pad 102a and the second pad 102b located in the first row 110 are to be utilized to conduct signals of the first differential pair. A third pad 102c located within the second column 116 and the second row 112, and a fourth pad 102d located within the third column 118 and the second row 112 are to be utilized to conduct signals of a second differential pair.

The pads 102 in the first row 110 have corresponding vias 106 that are offset from the pads 102 in substantially (within 5 degrees) a first direction. For example, a first via 106a that corresponds to the first pad 102a is offset from the first pad 102a in the first direction and a second via 106b that corresponds to the second pad 102b is offset from the second pad 102b in the first direction. Further, the pads in the second row 112 have corresponding vias 106 that are offset from the pads 102 in substantially (within 5 degrees) a second direction, where the second direction is different from the first direction. For example, a third via 106c that corresponds to the third pad 102c is offset from the third pad 102c in the second direction and a fourth via 106d that corresponds to the fourth pad 102d is offset from the fourth pad 102d in the second direction.

Accordingly, traces 108 corresponding to the first row 110 of pads 102 extend in substantially (within 5 degrees) the first direction and traces 108 corresponding to the second row 112 of pads 102 extend in substantially (within 5 degrees) the second direction. For example, a first trace 108a that couples the first pad 102a and the first via 106a extends from the first pad 102a to the first via 106a in the first direction. Further, a second trace 108b that couples the second pad 102b and the second via 106b extends from the second pad 102b to the second via 106b in the first direction. A third trace 108c that couples the third pad 102c and the third via 106c extends from the third pad 102c to the third via 106c in the second direction. Further, a fourth trace 108d that couples the fourth pad 102d and the fourth via 106d extends from the fourth pad 102d to the fourth pad 106d in the second direction. In some embodiments, the second direction is approximately (within 5 degrees) perpendicular to the first direction.

A pad 102 that is to conduct a signal of a first differential pair has a corresponding trace 108 that extends in a different direction than a trace 108 that corresponds to an adjacent pad 102 that is to conduct a signal of a second differential pair. For example, the first pad 102a is located adjacent to the third pad 102c. The first trace 108a that corresponds to the first pad 102a extends in a different direction than the third trace 108c that corresponds to the third pad 102c. The different directions in which the first trace 108a and the third trace 108c extend may be referred to as complementary directions. The first trace 108a and the third trace 108c extending in different directions can utilize the symmetry principle between the signal conducted by the first trace 108a and the signal conducted by the third trace 108c to reduce the crosstalk between the signals. Further, the first trace 108a and the third trace 108c extending in different directions may further cause a phase shift between the signals conducted by the first trace 108a and the third trace 108c. In some embodiments, the phase shift between the signals conducted by the first trace 108a and the third trace 108c may exhibit a 180-degree phase shift. The utilization of the symmetry principle and phase shift may exhibit less crosstalk between the signals, which may allow the pads 102 to conduct signals of higher frequency and/or with greater amounts of transmissions during a period than legacy routing layouts could support without issue. For example, the routing layout 100 can support signals of greater than or equal to 16 gigabits per second (Gbps), such as 16 Gbps, 25 Gbps, 32 Gbps, and/or 53 Gbps.

The pads 102 within the first column 114 and the pads 102 within the fourth column 120 are to be coupled to ground of the electrical routing component in which the routing layout 100 is implemented. The pads 102 of the second column 116 and the third column 118 are located between the pads 102 of the first column 114 and the fourth column 120. The pads 102 of the first column 114 and the fourth column 120 may isolate the pads 102 of the second column 116 and the third column 118 from pads 102 on the opposite side of the first column 114 and the fourth column 120, which may prevent or reduce crosstalk from signals conducted by the pads 102 on the opposite sides.

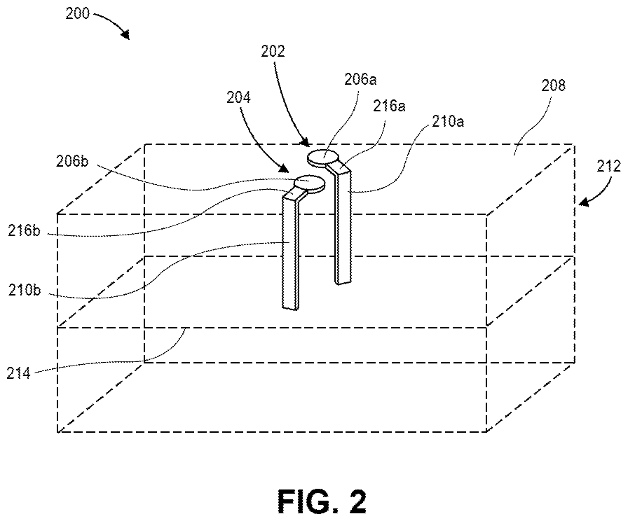

FIG. 2 illustrates a perspective view of a portion of an example electrical routing component 200 with example electrically conductive paths in accordance with the routing layout 100 of FIG. 1, according to various embodiments. In particular, FIG. 2 illustrates a first electrically conductive path 202 and a second electrically conductive path 204. Each of the first electrically conductive path 202 and the second electrically conductive path 204 include a pad, a trace, and a via, which include one or more of the features of the pads 102 (FIG. 1), the traces 108 (FIG. 1), and the vias 106 (FIG. 1), respectively. The first electrically conductive path 202 and the second electrically conductive path 204 provide representations of portions of the routing layout 100, as indicated. While only the first electrically conductive path 202 and the second electrically conductive path 204 are illustrated for clarity, it is to be understood that the electrical routing component 200 may include more than two electrically conductive paths in other embodiments.

The first electrically conductive path 202 includes a first pad 206a. The first pad 206a includes one or more of the features of the pads 102. The first pad 206a is located at a surface 208 of the electrical routing component 200.

The first electrically conductive path 202 further includes a first via 210a. The first via 210a includes one or more of the features of the vias 106. The first via 210a extends through a region 212 of the electrical routing component 200. For example, the first via 210a extends from the surface 208 through the region 212 to a surface 214 of the region 212 opposite to the surface 208. The first via 210a may be offset from the first pad 206a in a first direction.

The first electrically conductive path 202 further includes a first trace 216a. The first trace 216a includes one or more of the features of the traces 108. The first trace 216a extends along the surface 208, and couples the first pad 206a and the first via 210a. The first trace 216a extends in the first direction from the first pad 206a to the first via 210a.

The second electrically conductive path 204 includes a second pad 206b. The second pad 206b includes one or more of the features of the pads 102. The second pad 206b is located at the surface 208 of the electrical routing component 200.

The second electrically conductive path 204 further includes a second via 210b. The second via 210b includes one or more of the features of the vias 106. The second via 210b extends through the region 212 of the electrical routing component 200. For example, the second via 210b extends from the surface 208 through the region 212 to the surface 214 of the region 212 opposite to the surface 208. The second via 210b may be offset from the second pad 206b in a second direction that is different from the first direction. In some embodiments, the second direction is approximately (within 5 degrees) perpendicular to the first direction.

The second electrically conductive path 204 further includes a second trace 216b. The second trace 216b includes one or more of the features of the traces 108. The second trace 216b extends along the surface 208, and couples the second pad 206b and the second via 210b. The second trace 216b extends in the second direction from the second pad 206b to the second via 210b.

The first electrically conductive path 202 may be representative of the first pad 102a (FIG. 1), the first via 106a (FIG. 1), and the first trace 108a (FIG. 1). Further, the second electrically conductive path 204 may be representative of the third pad 102c (FIG. 1), the third via 106c (FIG. 1), and the third trace 108c (FIG. 1). In particular, the first electrically conductive path 202 and the second electrically conductive path 204 illustrates a perspective view of the first pad 102a, the first via 106a, the first trace 108a, the third pad 102c, the third via 106c, and the third trace 108c, respectively, in accordance with some embodiments.

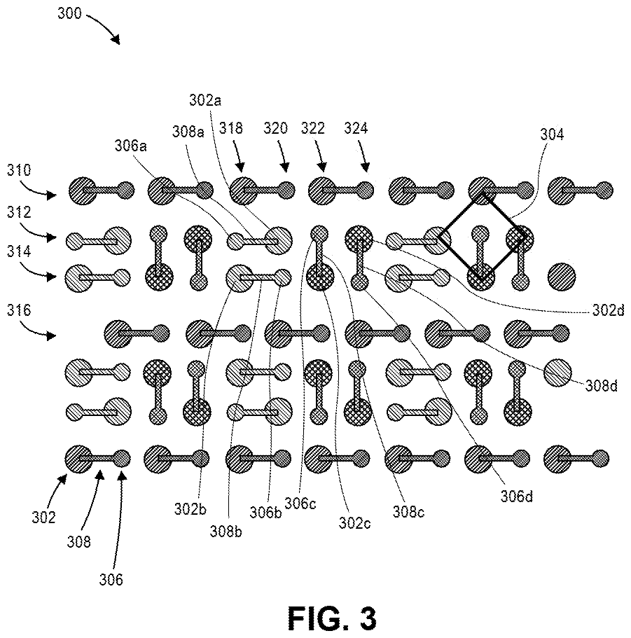

FIG. 3 illustrates a top view of another example routing layout 300 to be implemented by an electrical routing component (such as the electrical routing component 200 (FIG. 2)), according to various embodiments. In particular, the routing layout 300 illustrates a plurality of electrically conductive paths, or portions thereof, that are to be implemented by an electrical routing component. Each of the electrically conductive paths can be coupled to a component that produces a signal or a ground for the electrical routing component, as described throughout. In the illustrated embodiment, each of the electrically conductive paths include a pad, a via, and a trace.

The routing layout 300 includes a plurality of pads 302. The pads 302 comprise electrically conductive elements to which a component (such as a processor, an integrated circuit substrate, and/or other computer hardware) can be mounted and to which leads of the component can be electrically coupled. For example, the pads 302 can form a ball grid array or a land grid array, or can comprise a plurality of plated holes to which the component may be mounted. The pads 302 are located at a surface of the electrical routing component. In other embodiments, the pads are located at a surface of a region or a layer of the electrical routing component. The pads 302 are arranged in a trapezoidal pad pattern, where each group of four adjacent pads 302 form a trapezoid, such as trapezoid 304. The pads 302 located adjacent to each other may be referred to as being located at complementary positions.

The routing layout 300 further includes a plurality of vias 306. The vias 306 extend through a region (such as the region 212 (FIG. 2)) of the electrical routing component. For example, the vias 306 extend through a layer of the electrical routing component in some embodiments. The vias 306 extend from the surface at which the pads 302 are located through the region to a surface at the opposite side of the region. A number of the vias 306 is equal to the number of pads 302, where each via 306 corresponds to one of the pads 302.

The routing layout 300 further includes a plurality of traces 308. Each of the traces 308 couple a pad 302 with a corresponding via 306. The traces 308 extend from the pad 302 to the corresponding via 306 along the surface where the pads 302 are located.

For brevity, the following description refers to a first row 310, a second row 312, a third row 314, a fourth row 316, a first column 318, a second column 320, a third column 322, and a fourth column 324 of the pads 302. It is to be understood that the features and/or arrangement described in relation to the first row 310, second row 312, third row 314, fourth row 316, first column 318, second column 320, third column 322, and fourth column 324 are representative of the features and/or arrangements of other rows and columns of the pads 302 of the routing layout 300.

The second row 312 and the third row 314 of the pads 302 are to be utilized to conduct signals of differential pairs. The pads 302 within the second row 312 and the third row 314 may be paired such that a pad 302 within the second row 312 and a pad 302 within the third row 314 and in an adjacent column to the pad 302 within the second row 312 are to conduct signals corresponding to a single differential pair. For example, a first pad 302a located within the second row 312 and the second column 320 is to be utilized to conduct a first signal of a first differential pair, and a second pad 302b located within the third row 314 and the first column 318 is to be utilized to conduct a second signal of the first differential pair.

The paired pads 302 located within adjacent columns to other paired pads 302 are to be utilized to conduct signals of a different differential pair from the other paired pads 302. For example, the first pad 302a and the second pad 302b located in the second column 320 and the first column 318, respectively, are to be utilized to conduct signals of the first differential pair. A third pad 302c located within the third column 322 and a fourth pad 302d located within the fourth column 324 are to be utilized to conduct signals of a second differential pair.

Pads 302 within a pair of pads 302 have corresponding vias 306 that are offset from the pads 302 in substantially (within 5 degrees) opposing directions. Further, the corresponding via 306 of one of the pads 302 within the pair of pads 302 may be located adjacent to the other pad 302 in the pair of pads. For example, a first via 306a that corresponds to the first pad 302a is offset from the first pad 302a in a first direction and a second via 306b that corresponds to the second pad 302b is offset from the second pad 302b in a second direction that is opposite to the first direction. Further, the vias 306 corresponding to adjacent pairs of pads 302 are offset from the pads 302 in different directions from each other. For example, a third via 306c that corresponds to the third pad 302c extends from the third pad 302c in a third direction that is different from both the first direction and the second direction. A fourth via 306d that corresponds to the fourth pad 302d extends from the fourth pad 302d in a fourth direction that is different from both the first direction and the second direction, and opposite to the third direction.

Accordingly, a first trace 308a that corresponds to the first pad 302a extends from the first pad 302a in the first direction and a second trace 308b that corresponds to the second pad 302b extends from the second pad 302b in the second direction. Further, a third trace 308c that corresponds to the third pad 302c extends from the third pad 302c in the third direction and a fourth trace 308d that corresponds to the fourth pad 302d extends from the fourth pad 302d in the fourth direction. In some embodiments, the third direction may be approximately (within 5 degrees) perpendicular to the first direction and the second direction, and the fourth direction may be approximately (within 5 degrees) perpendicular to the first direction and the second direction.

A pad 302 that is to conduct a signal of a first differential pair has a corresponding trace 308 that extends in a different direction than a trace 308 that corresponds to an adjacent pad 302 that is to conduct a signal of a second differential pair. For example, the first pad 302a is located adjacent to the fourth pad 302d within the second row 312. The first trace 308a that corresponds to the first pad 302a extends in a different direction than the fourth trace 308d that corresponds to the fourth pad 302d. The different directions in which the first trace 308a and the fourth trace 308d extend may be referred to as complementary directions. The first trace 308a and the fourth trace 308d extending in different directions can utilize the symmetry principle between the signal conducted by the first trace 308a and the signal conducted by the fourth trace 308d to reduce the crosstalk between the signals. Further, the first trace 308a and the fourth trace 308d extending in different directions may further cause a phase shift between the signals conducted by the first trace 308a and the fourth trace 308d. In some embodiments, the phase shift between the signals conducted by the first trace 308a and the fourth trace 308d may exhibit a 180-degree phase shift. The utilization of the symmetry principle and phase shift may exhibit less crosstalk between the signals, which may allow the pads 302 to conduct signals of higher frequency and/or with greater amounts of transmissions during a period than legacy routing layouts could support without issue. For example, the routing layout 100 can support signals of greater than or equal to 16 gigabits per second (Gbps), such as 16 Gbps, 25 Gbps, 32 Gbps, and/or 53 Gbps.

The pads 302 within the first row 310 and the pads 302 within the fourth row 316 are to be coupled to ground of the electrical routing component in which the routing layout 300 is implemented. The pads 302 of the second row 312 and the third row 314 are located between the pads 302 of the first row 310 and the fourth row 316. The pads 302 of the first row 310 and the fourth row 316 may isolate the pads 302 of the second row 312 and the third row 314 from pads 302 on the opposite side of the first row 310 and the fourth row 316, which may prevent or reduce crosstalk from signals conducted by the pads 302 on the opposite sides.

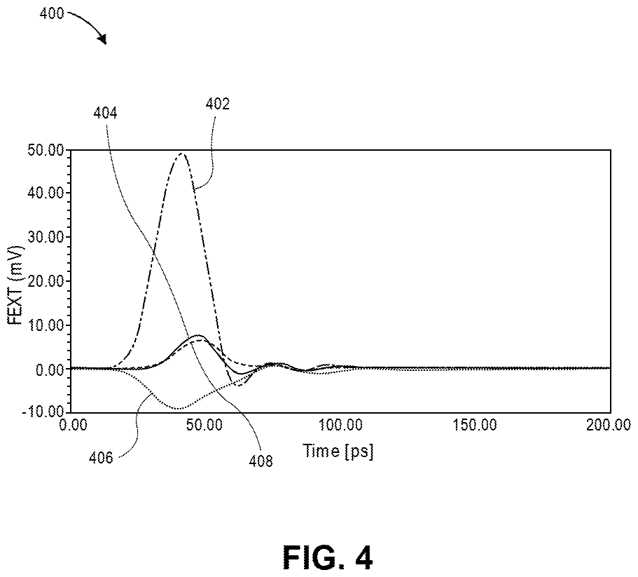

FIG. 4 illustrates a chart 400 showing example crosstalk measurement acting upon a differential signal in a routing layout, according to various embodiments. In particular, the chart illustrates crosstalk measurements of legacy routing versus crosstalk measurements of the routing layout 100 (FIG. 1).

The chart 400 includes line 402 that illustrates the crosstalk effect of a first aggressor upon the differential signal with the legacy routing layout. The differential signal is conducted by a first pair of pads and the first aggressor comprises a second pair of pads located adjacent to the first pair of pads, where the second pair of pads conduct a second differential signal. For example, the first pair of pads would be the first pad 102a (FIG. 1) and the second pad 102b (FIG. 1) in the routing layout 100, and the first aggressor would be the third pad 102c and the fourth pad 102d in the routing layout 100. As can be seen from line 402, the first aggressor has approximately a 50 millivolt (mV) crosstalk effect on the differential signal in the legacy routing layout.

Further, the chart 400 includes line 404 that illustrates the crosstalk effect of a second aggressor upon the differential signal with the legacy routing layout. The second aggressor comprises a third pair of pads located on an opposite side of the first aggressor from the first pair of pads that conduct the differential signal. As can be seen from line 404, the second aggressor has approximately an 8 mV crosstalk effect on the differential signal in the legacy routing layout.

The chart includes line 406 that illustrates the crosstalk effect of a first aggressor upon the differential signal with the routing layout 100. As can be seen from line 406, the first aggressor has approximately a 10 mV crosstalk effect on the differential signal in the routing layout 100. Further, the 10 mV crosstalk effect is shown being negative, which is due to a 180-degree phase shift. The 10 mV crosstalk effect in the routing layout 100 is an improvement from the 50 mV crosstalk effect due to the first aggressor exhibited in the legacy routing layout.

The chart includes line 408 that illustrates the crosstalk effect of a second aggressor upon the differential signal with the routing layout 100. As can be seen from the line 408, the second aggressor has approximately a 6 mV crosstalk effect on the differential signal in the routing layout. The 6 mV crosstalk effect in the routing layout is an improvement from the 8 mV crosstalk effect due to the second aggressor exhibited in the legacy routing layout.

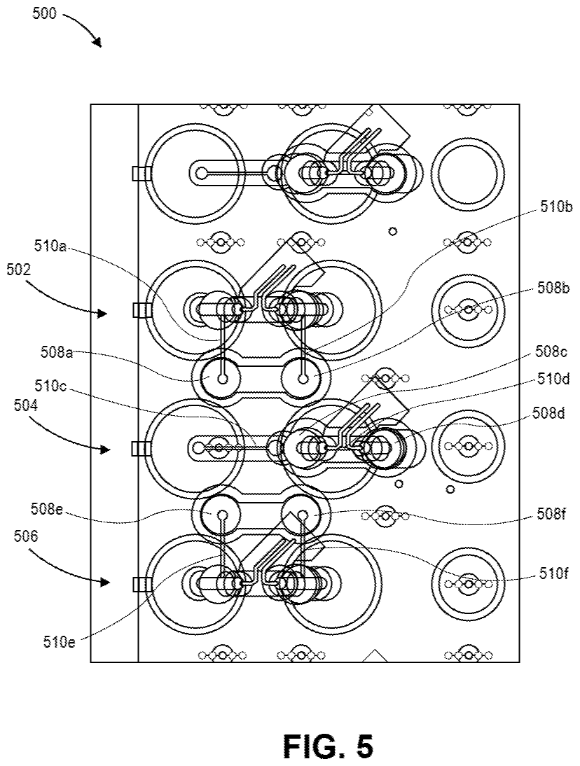

FIG. 5 illustrates a portion of an example package 500, according to various embodiments. In particular, the illustrated package 500 implements a zigzag design at a plated through hole area. The zigzag design may be implemented in addition to the routing layout 100 (FIG. 1) or the routing layout 300 (FIG. 3), in some embodiments. For brevity, a first pair 502, a second pair 504, and a third pair 506 of electrically conductive paths are referred to. The first pair 502 is to conduct signals associated with a first differential pair, the second pair 504 is to conduct signals associated with a second differential pair, and the third pair 506 is to conduct signals associated with a third differential pair.

The first pair 502 includes a first plated through hole via 508a and a second plated through hole via 508b. The first pair 502 further includes a first trace 510a coupled to the first plated through hole via 508a and a second trace 510b coupled to the second through hole via 508b. The first trace 510a and the second trace 510b extend to the first plated through hole via 508a and the second plated through hole via 508b, respectively, in substantially (within 5 degrees) a first direction.

The second pair 504 includes a third plated through hole via 508c and a fourth plated through hole via 508d. The second pair 504 further includes a third trace 510c coupled to the third plated through hole via 508c and a fourth trace 510d coupled to the fourth through hole via 508d. The third trace 510c and the fourth trace 510d extend to the third plated through hole via 508c and the fourth plated through hole via 508d, respectively, in substantially (within 5 degrees) a second direction that is different than the first direction. In some embodiments, the second direction may be approximately (within 5 degrees) perpendicular to the first direction.

The third pair 506 includes a fifth plated through hole via 508e and a sixth plated through hole via 508f. The third pair 506 further includes a fifth trace 510e coupled to the fifth plated through hole via 508e and a sixth trace 510f coupled to the sixth through hole via 508f. The fifth trace 510e and the sixth trace 510f extend to the fifth plated through hole via 508e and the sixth plated through hole via 508f, respectively, in substantially (within 5 degrees) a third direction. In some embodiments, the third direction is approximately (within 5 degrees) opposite to the first direction and approximately (within 5 degrees) perpendicular to the second direction.

When implemented with the routing layout 100 or the routing layout 300, the arrangement of the first pair 502, the second pair 504, and the third pair 506 may cause the crosstalk at the plated through hole area to have an opposite polarity than at the pads 102 (FIG. 1) or the pads 302 (FIG. 3), which is referred to as polarity reversal. The opposite polarity may cause the crosstalk to be reduced due to the crosstalk produced at the pads 102 or the pads 302 being cancelled by the crosstalk at the plated through hole area.

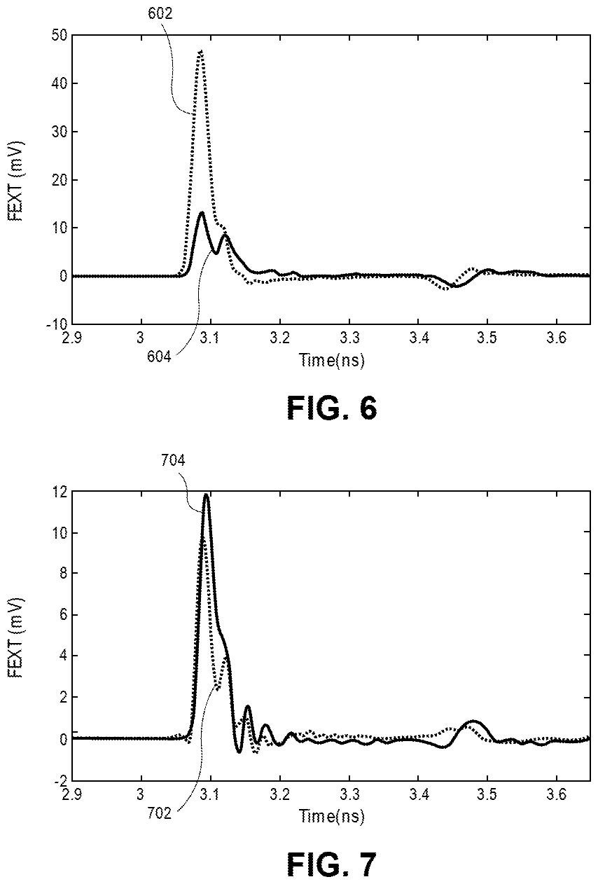

FIG. 6 and FIG. 7 illustrate charts showing example crosstalk measurements acting upon a differential signal for the package of FIG. 5, according to various embodiments. In particular, the charts show crosstalk measurements when the zigzag design of FIG. 5 is implemented with the routing layout 100 (FIG. 1) or the routing layout 300 (FIG. 3).

FIG. 6 illustrates a crosstalk measurement of a first aggressor acting upon a victim. The first pair 502 (FIG. 5) may be the victim and the second pair 504 (FIG. 5) may be the first aggressor. Line 602 shows the crosstalk effect of the first aggressor on the victim with the legacy routing layouts. As can be seen, the crosstalk effect with legacy routing layouts is approximately 47 mV at the maximum value. Line 604 shows the crosstalk effect of the first aggressor on the victim with the zigzag design and the routing layout 100 or the routing layout 300. As can be seen, the crosstalk effect shown by line 604 is approximately 13 mV at the maximum value.

FIG. 7 illustrates a crosstalk measurement of a second aggressor acting upon a victim. The first pair 502 (FIG. 5) may be the victim and the third pair 506 (FIG. 5) may be the second aggressor. Line 702 shows the crosstalk effect of the second aggressor on the victim with the legacy routing layouts. As can be seen, the crosstalk effect with legacy routing layouts is approximately 9.7 mV at the maximum value. Line 704 shows the crosstalk effect of the second aggressor on the victim with the zigzag design and the routing layout 100 or the routing layout 300. As can be seen, the crosstalk effect shown by line 704 is approximately 11.9 mV at the maximum value. While the crosstalk effect of the second aggressor may be increased with the zigzag design, the overall crosstalk effect is lower due to the decrease in the crosstalk effect of the first aggressor.

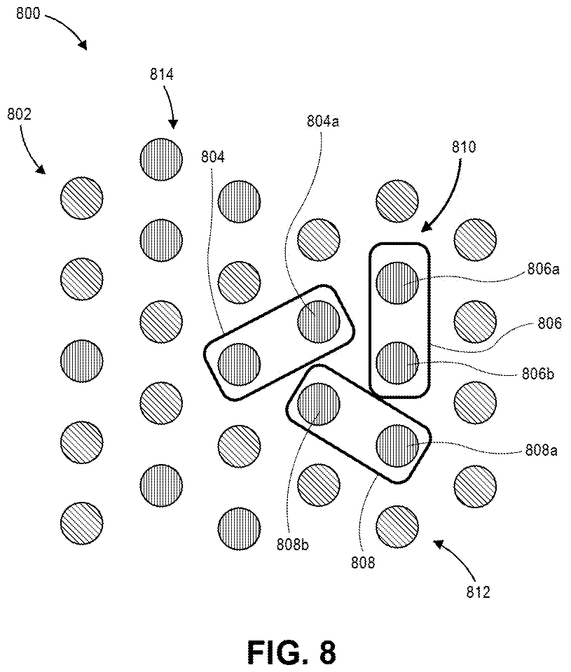

FIG. 8 illustrates an example pad pattern 800 that may be implemented by a computer component or an electrical routing component (such as the electrical routing component 200 (FIG. 2)), according to various embodiments. In some embodiments, the pad pattern 800 may be implemented for a variety of server products, such as computer processing units and platform controller hubs.

The pad pattern 800 can include a plurality of pads 802. The pads 802 include one or more of the features of the pads 102 (FIG. 1). In other embodiments, the pad pattern 800 may be implemented for a plurality of pins of a computer component, where each of the pads 802 illustrated may be replaced by a pin.

The pad pattern 800 includes a first group of pads 810 that are to conduct signals of a plurality of differential pairs. The first group of pads 810 include a first pair of pads 804. The first pair of pads 804 are to conduct signals associated with a first differential pair. The first pair of pads 804 are oriented in a first direction.

The first group of pads 810 includes a second pair of pads 806. The second pair of pads 806 are to conduct signals associated with a second differential pair. The second pair of pads 806 are oriented in a second direction that is different from the first direction. In some embodiments, the second direction forms an angle of approximately (within 5 degrees) 60 degrees with the first direction. The second pair of pads 806 being oriented in a different direction than the first pair of pads 804 may reduce crosstalk between the signals of the first differential pair and the second differential pair. Further, a pad 806a of the second pair of pads 806 is located adjacent to a pad 804a of the first pair of pads 804 in some embodiments.

The first group of pads 810 includes a third pair of pads 808. The third pair of pads 808 are to conduct signals associated with a third differential pair. The third pair of pads 808 are oriented in a third direction that is different from the first direction and the second direction. In some embodiments, the third direction forms an angle of approximately (within 5 degrees) 60 degrees with the first direction and approximately (within 5 degrees) 60 degrees with second direction. The third pair of pads 808 being oriented in a different direction than the first pair of pads 804 and the second pair of pads 806 may reduce crosstalk between the signals of the first differential pair, the second differential pair, and the third differential pair. Further, a pad 808a of the third pair of pads 808 is located adjacent to a pad 806b of the second pair of pads 806 in some embodiments. Another pad 808b of the third pair of pads 808 is located adjacent to a pad 804a of the first pair of pads 804.

The pad pattern 800 further includes a second group of pads 812 that are to couple to a ground of the computer component or electrical routing component in which the pad pattern 800 is implemented. The second group of pads 812 surrounds the first group of pads 810. For example, the second group of pads 812 forms a triangle around the first group of pads 810. The second group of pads 812 are located between the first group of pads 810 and a third group of pads 814 that are to conduct signals of other differential pairs. Accordingly, the second group of pads 812 separate the first group of pads 810 from the third group of pads 814 and may isolate the first group of pads 810 from the third group of pads 814. The second group of pads 812 being coupled to ground may prevent or reduce crosstalk between the first group of pads 810 and the third group of pads 814. The pad pattern 800 may be referred to as a triangular pattern.

In some embodiments, one or more of the first pair of pads 804, the second pair of pads 806, and the third pair of pads 808 may be omitted from the first group of pads 810. For example, the first group of pads 810 may include only the first pair of pads 804 and the second pair of pads 806 in some embodiments, where the second group of pads 812 surround the first pair of pads 804 and the second pair of pads 806.

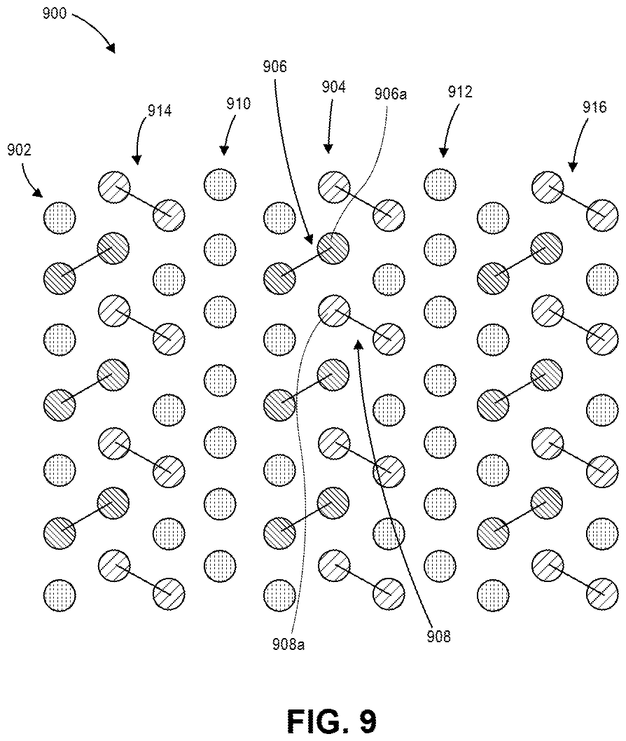

FIG. 9 illustrates another example pad pattern 900 that may be implemented by a computer component or an electrical routing component (such as the electrical routing component 200 (FIG. 2)), according to various embodiments. In some embodiments, the pad pattern 900 may be implemented for a variety of server products, such as computer processing units and platform controller hubs.

The pad pattern 900 can include a plurality of pads 902. The pads 902 include one or more of the features of the pads 102 (FIG. 1). In other embodiments, the pad pattern 900 may be implemented for a plurality of pins of a computer component, where each of the pads 902 illustrated may be replaced by a pin.

The pad pattern 900 includes a plurality of paired pads, where each pad within a pair of pads is to conduct one signal of a differential pair. In the illustrated embodiment, lines are shown connecting pads 902 that form a pair of pads.

The pad pattern 900 includes a first group of pads 904 that are to conduct signals of a plurality of differential pairs. The first group of pads 904 includes a plurality of paired pads. For brevity, a first pair of pads 906 and a second pair of pads 908 of the first group of pads 904 are described. The first group of pads 904 includes a first pair of pads 906. The first pair of pads 906 are to conduct signals associated with a first differential pair. The first pair of pads 906 are oriented in a first direction.

The first group of pads 904 further includes a second pair of pads 908. The second pair of pads 908 are to conduct signals associated with a second differential pair. The second pair of pads 908 are oriented in a second direction that is different from the first direction. In some embodiments, the second direction forms an angle of approximately (within 5 degrees) 60 degrees with the first direction. The second pair of pads 908 being oriented in a different direction than the first pair of pads 906 may reduce crosstalk between the signals of the first differential pair and the second differential pair. Further, a pad 908a of the second pair of pads 908 is located adjacent to a pad 906a of the first pair of pads 906 in some embodiments.

The pad pattern 900 further includes a second group of pads 910 and a third group of pads 912 that are to couple to a ground of the computer component or electrical routing component in which the pad pattern 900 is implemented. The second group of pads 910 are located on a first side of the first group of pads 904 and the third group of pads 912 are located on a second side of the first group of pads 904, where the second side is opposite to the first side. The second group of pads 910 are located between the first group of pads 904 and a fourth group of pads 914 that are to conduct signals of other differential pairs. Further, the third group of pads 912 are located between the first group of pads 904 and a fifth group of pads 916. The second group of pads 910 separate the first group of pads 904 from the fourth group of pads 914 and may isolate the first group of pads 904 from the fourth group of pads 914. The second group of pads 910 being coupled to ground may prevent or reduce crosstalk between the first group of pads 904 and the fourth group of pads 914. The third group of pads 912 separate the first group of pads 904 from the fifth group of pads 916 and may isolate the first group of pads 904 from the fifth group of pads 916. The third group of pads 912 being coupled to ground may prevent or reduce crosstalk between the first group of pads 904 and the fifth group of pads 916. The pad pattern 900 may be referred to as a zigzag pattern. In some embodiments, the third group of pads 912 and the fifth group of pads 916 may be omitted.

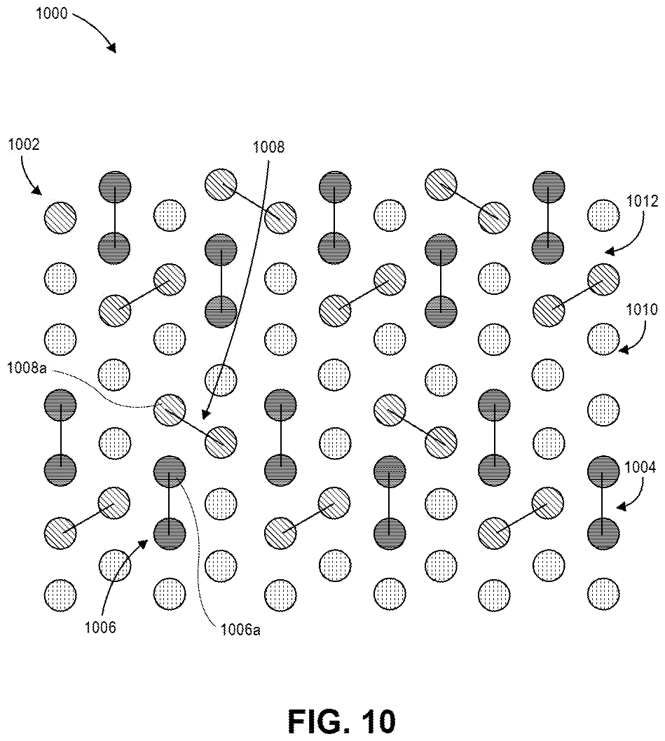

FIG. 10 illustrates another example pad pattern 1000 that may be implemented by a computer component or an electrical routing component (such as the electrical routing component 200 (FIG. 2)), according to various embodiments. In some embodiments, the pad pattern 1000 may be implemented for a variety of server products, such as computer processing units and platform controller hubs.

The pad pattern 1000 can include a plurality of pads 1002. The pads 1002 include one or more of the features of the pads 102 (FIG. 1). In other embodiments, the pad pattern 1000 may be implemented for a plurality of pins of a computer component, where each of the pads 1002 illustrated may be replaced by a pin.

The pad pattern 1000 includes a plurality of paired pads, where each pad within a pair of pads is to conduct one signal of a differential pair. In the illustrated embodiment, lines are shown connecting pads 1002 that form a pair of pads.

The pad pattern 1000 includes a first group of pads 1004 that are to conduct signals of a plurality of differential pairs. The first group of pads 1004 includes a plurality of paired pads. For brevity, a first pair of pads 1006 and a second pair of pads 1008 of the first group of pads 1004 are described. The first group of pads 1004 includes a first pair of pads 1006. The first pair of pads 1006 are to conduct signals associated with a first differential pair. The first pair of pads 1006 are oriented in a first direction.

The first group of pads 1004 further includes a second pair of pads 1008. The second pair of pads 1008 are to conduct signals associated with a second differential pair. The second pair of pads 1008 are oriented in a second direction that is different from the first direction. In some embodiments, the second direction forms an angle of approximately (within 5 degrees) 60 degrees with the first direction. The second pair of pads 1008 being oriented in a different direction than the first pair of pads 1006 may reduce crosstalk between the signals of the first differential pair and the second differential pair. Further, a pad 1008a of the second pair of pads 1008 is located adjacent to a pad 1006a of the first pair of pads 1006 in some embodiments.

The pad pattern 1000 further includes a second group of pads 1010 that are to couple to a ground of the computer component or electrical routing component in which the pad pattern 1000 is implemented. The second group of pads 1010 are located on a side of the first group of pads 1004. The second group of pads 1010 are located between the first group of pads 1004 and a third group of pads 1012 that are to conduct signals of other differential pairs. The second group of pads 1010 separate the first group of pads 1004 from the third group of pads 1012 and may isolate the first group of pads 1004 from the third group of pads 1012. The second group of pads 1010 being coupled to ground may prevent or reduce crosstalk between the first group of pads 1004 and the third group of pads 1012. The pad pattern 1000 may be referred to as a zigzag pattern.

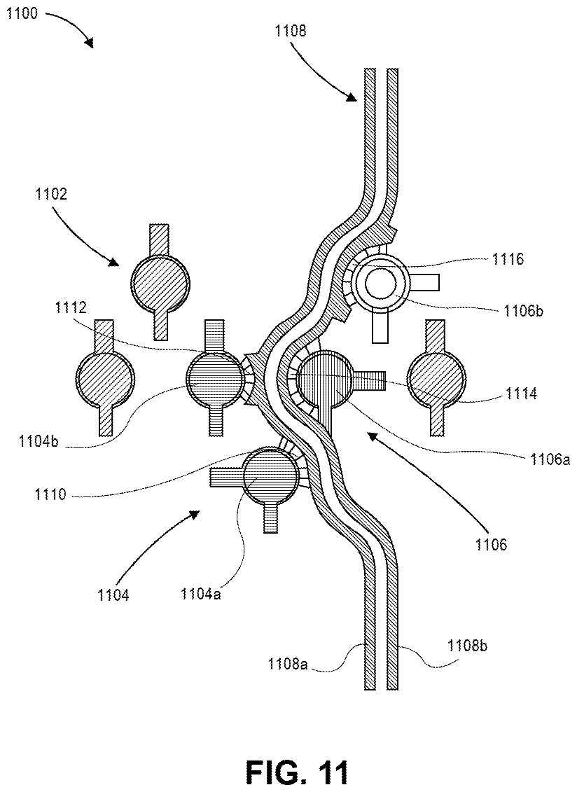

FIG. 11 illustrates a top view of an example routing pattern 1100 that may be implemented by an electrical routing component, according to various embodiments. In particular, the routing pattern 1100 illustrated shows a cross-sectional view of the electrical routing component.

The routing pattern 1100 includes a plurality of vias 1102. The vias 1102 can be utilized for conduction of signals or coupling to a ground of the electrical routing component in which the routing pattern 1100 is implemented. In the illustrated embodiment, a first pair of vias 1104 are to transmit signals associated with a first differential pair. A second pair of vias 1106 are to transmit signals associated with a second differential pair. The routing pattern 1100 further includes a pair of traces 1108. The pair of traces 1108 are formed of a conductive material, such as copper, silver, gold, aluminum, nickel, tin, or some combination thereof. The pair of traces 1108 are routed between the first pair of vias 1104 and the second pair of vias 1106.

Due to the pair of traces 1108 being within a proximity of the first pair of vias 1104 and the second pair of vias 1106, the first differential pair conducted by the first pair of vias 1104 and the second differential pair conducted by the second pair of vias 1106 may produce crosstalk with the signals conducted by the pair of traces 1108. The amount of crosstalk caused by the first pair of vias 1104 and the second pair of vias 1106 is dependent on the coupling between each of the vias and the traces, where the coupling is dependent on the distance between the vias and the traces and the amount of surface area between the vias and the traces. In legacy embodiments where a cross-sectional area of the traces are uniform, the amount of crosstalk caused by each of the vias within the first pair of vias 1104 and/or the second pair of vias 1106 could be unbalanced (i.e., vias within each of the pairs would cause different amounts of crosstalk). The unbalanced crosstalk of the legacy embodiments could have detrimental effects on the signals conducted by the first pair of vias 1104, the second pair of vias 1106, and/or the pair of traces 1108.

To address the unbalanced crosstalk concern, additional material may be added to the traces to balance the crosstalk caused by the first pair of vias 1104 and the second pair of vias 1106. For example, a coupling between a first trace 1108a of the pair of traces 1108 and a first via 1104a of the first pair of vias 1104 is mainly caused by the distance and cross-sectional area between the first trace 1108a and the first via 1104a within the area 1110. In order to balance the coupling with a second via 1104b of the first pair of vias 1104, the first trace 1108a includes additional conductive material in an area located adjacent to the second via 1104b, which increases the cross-sectional area of the first trace 1108a at the area. For example, a width of the first trace 1108a is increased at area 1112. In other embodiments, a thickness of the first trace 1108a may be increased at the area 1112, a width of the first trace 1108a may be increased at the area 1112, or some combination thereof. An amount of the increase in the cross-sectional area of the first trace 1108a at the area 1112 can be selected such that a coupling between the first trace 1108a and the second via 1104b is approximately (within 5%) equal to the coupling between the first trace 1108a and the first via 1104a. Based on the coupling being approximately equal, the crosstalk caused by the first via 1104a and the crosstalk caused by the second via 1104b to the first trace 1108a can be approximately (within 5%) balanced. Balancing the crosstalk may reduce the crosstalk (such as up to the 16 gigahertz (GHz) range), allow more conductive elements (for example, vias, traces, and pads) to positioned within an area, or some combination thereof.

Further, additional material may be added to a second trace 1108b of the pair of traces 1108 to address the unbalanced crosstalk concern. For example, a coupling between the second trace 1108b and a first via 1106a of the second pair of vias 1106 is mainly caused by the distance and cross-sectional area between the second trace 1108b and the first via 1106a within the area 1114. In order to balance the coupling with a second via 1106b of the second pair of vias 1106, the second trace 1108b includes additional conductive material in an area located adjacent to the second via 1106b, which increases the cross-sectional area of the second trace 1108b at the area. For example, a width of the second trace 1108b is increased at area 1116. In other embodiments, a thickness of the second trace 1108b may be increased at the area 1116, a width of the second trace 1108b may be increased at the area 1116, or some combination thereof. An amount of the increase in the cross-sectional area of the second trace 1108b at the area 1116 can be selected such that a coupling between the second trace 1108b and the second via 1106b is approximately (within 5%) equal to the coupling between the second trace 1108b and the first via 1106a. Based on the coupling being approximately equal, the crosstalk caused by the first via 1106a and the crosstalk caused by the second via 1106b to the second trace 1108b can be approximately (within 5%) balanced. Balancing the crosstalk may reduce the crosstalk (such as up to the 16 gigahertz (GHz) range), allow more conductive elements (for example, vias, traces, and pads) to positioned within an area, or some combination thereof.

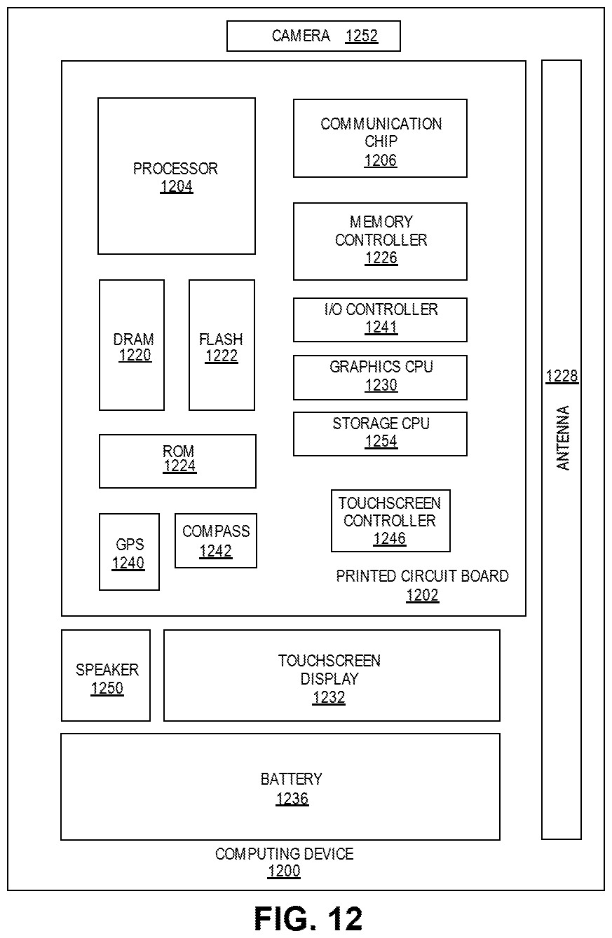

FIG. 12 illustrates an example computer device 1200 that may employ the apparatuses and/or methods described herein (e.g., the routing layout 100, the electrical routing component 200, the routing layout 300, the package 500, the pad pattern 800, the pad pattern 900, the pad pattern 1000, and the routing pattern 1100), in accordance with various embodiments. As shown, computer device 1200 may include a number of components, such as one or more processor(s) 1204 (one shown) and at least one communication chip 1206. In various embodiments, the one or more processor(s) 1204 each may include one or more processor cores. In various embodiments, the at least one communication chip 1206 may be physically and electrically coupled to the one or more processor(s) 1204. In further implementations, the communication chip 1206 may be part of the one or more processor(s) 1204. In various embodiments, computer device 1200 may include printed circuit board (PCB) 1202. For these embodiments, the one or more processor(s) 1204 and communication chip 1206 may be disposed thereon. In alternate embodiments, the various components may be coupled without the employment of PCB 1202.

Depending on its applications, computer device 1200 may include other components that may or may not be physically and electrically coupled to the PCB 1202. These other components include, but are not limited to, memory controller 1226, volatile memory (e.g., dynamic random access memory (DRAM) 1220), non-volatile memory such as read only memory (ROM) 1224, flash memory 1222, storage device 1254 (e.g., a hard-disk drive (HDD)), an I/O controller 1241, a digital signal processor (not shown), a crypto processor (not shown), a graphics processor 1230, one or more antenna 1228, a display (not shown), a touch screen display 1232, a touch screen controller 1246, a battery 1236, an audio codec (not shown), a video codec (not shown), a global positioning system (GPS) device 1240, a compass 1242, an accelerometer (not shown), a gyroscope (not shown), a speaker 1250, a camera 1252, and a mass storage device (such as hard disk drive, a solid state drive, compact disk (CD), digital versatile disk (DVD)) (not shown), and so forth.

In some embodiments, the one or more processor(s) 1204, flash memory 1222, and/or storage device 1254 may include associated firmware (not shown) storing programming instructions configured to enable computer device 1200, in response to execution of the programming instructions by one or more processor(s) 1204, to practice all or selected aspects of the methods described herein. In various embodiments, these aspects may additionally or alternatively be implemented using hardware separate from the one or more processor(s) 1204, flash memory 1222, or storage device 1254.

In various embodiments, one or more components of the computer device 1200 may implement the routing layout 100 (FIG. 1), the electrical routing component 200 (FIG. 2), the routing layout 300 (FIG. 3), the package 500 (FIG. 5), the pad pattern 800 (FIG. 8), the pad pattern 900 (FIG. 9), the pad pattern 1000 (FIG. 10), the routing pattern 1100 (FIG. 11), or some combination thereof. For example, the PCB 1202 may implement and/or comprise the routing layout 100, the electrical routing component 200, the routing layout 300, the package 500, the pad pattern 800, the pad pattern 900, the pad pattern 1000, and/or the routing pattern 1100 in some embodiments. Further, substrate packages utilized for coupling the processor 1204, the DRAM 1220, the flash memory 1222, the ROM 1224, the communication chip 1206, the memory controller 1226, the I/O controller 1241, the graphics CPU 1230, the storage device 1254, and/or the touch screen controller 1246 to the PCB 1202 may implement and/or comprise the routing layout 100, the electrical routing component 200, the routing layout 300, the package 500, the pad pattern 800, the pad pattern 900, the pad pattern 1000, and/or the routing pattern 1100 in some embodiments.

The communication chips 1206 may enable wired and/or wireless communications for the transfer of data to and from the computer device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1206 may implement any of a number of wireless standards or protocols, including but not limited to IEEE 802.20, Long Term Evolution (LTE), LTE Advanced (LTE-A), General Packet Radio Service (GPRS), Evolution Data Optimized (Ev-DO), Evolved High Speed Packet Access (HSPA+), Evolved High Speed Downlink Packet Access (HSDPA+), Evolved High Speed Uplink Packet Access (HSUPA+), Global System for Mobile Communications (GSM), Enhanced Data rates for GSM Evolution (EDGE), Code Division Multiple Access (CDMA), Time Division Multiple Access (TDMA), Digital Enhanced Cordless Telecommunications (DECT), Worldwide Interoperability for Microwave Access (WiMAX), Bluetooth, derivatives thereof, as well as any other wireless protocols that are designated as 3G, 4G, 5G, and beyond. The computer device 1200 may include a plurality of communication chips 1206. For instance, a first communication chip 1206 may be dedicated to shorter range wireless communications such as Wi-Fi and Bluetooth, and a second communication chip 1206 may be dedicated to longer range wireless communications such as GPS, EDGE, GPRS, CDMA, WiMAX, LTE, Ev-DO, and others.

In various implementations, the computer device 1200 is a server, in particular, a server in a data center offering cloud computing to a number of remote client devices. In other implementations, the computer device 1200 may be a laptop, a netbook, a notebook, an ultrabook, a smartphone, a computer tablet, a personal digital assistant (PDA), an ultra-mobile PC, a mobile phone, a desktop computer, a printer, a scanner, a monitor, a set-top box, an entertainment control unit (e.g., a gaming console or automotive entertainment unit), a digital camera, an appliance, a portable music player, or a digital video recorder. In further implementations, the computer device 1200 may be any other electronic device that processes data.

Example 1 may include an apparatus for a computer device, comprising a first electrically conductive path that extends through a region of the apparatus, wherein the first electrically conductive path includes a first pad located at a surface of the region, a first via that extends through the region, and a first trace that couples the first pad and the first via, wherein the first trace extends in a first direction, and a second electrically conductive path that extends through the region, wherein the second electrically conductive path includes a second pad located at the surface of the region and adjacent to the first pad, a second via that extends through the region, and a second trace that couples the second pad and the second via, wherein the second trace extends in a second direction that is different from the first direction.

Example 2 may include the apparatus of example 1 or any other example herein, wherein the second direction is approximately perpendicular to the first direction.

Example 3 may include the apparatus of example 1 or any other example herein, wherein the first pad and the second pad are located within a square pad pattern, and wherein the first pad and the second pad are located at adjacent positions within the square pad pattern.

Example 4 may include the apparatus of example 1 or any other example herein, wherein the first pad and the second pad are located within a trapezoidal pad pattern, and wherein the first pad and the second pad are located at adjacent positions within the trapezoidal pad pattern.

Example 5 may include the apparatus of example 1 or any other example herein, wherein the first pad and the second pad are included within a ball grid array formed at the surface of the region.

Example 6 may include the apparatus of example 1 or any other example herein, wherein the first trace and the second trace extend along the surface of the region.

Example 7 may include the apparatus of example 1 or any other example herein, wherein the region is a layer of the apparatus.

Example 8 may include the apparatus of example 1 or any other example herein, wherein the first electrically conductive path is to conduct a signal of a first differential pair, and wherein the second electrically conductive path is to conduct a signal of a second differential pair.

Example 9 may include the apparatus of example 1 or any other example herein, wherein the apparatus is a printed circuit board.

Example 10 may include the apparatus of example 1 or any other example herein, wherein the apparatus is an integrated circuit substrate.

Example 11 may include a computer device, comprising a processor, and an electrical routing component coupled to the processor, the electrical routing component to conduct signals of differential pairs for the processor, wherein the electrical routing component includes a first electrically conductive path to conduct a signal of a first differential pair, wherein the first electrically conductive path extends through a region and includes a first pad and a first trace, and a second electrically conductive path to conduct a signal of a second differential pair, wherein the second electrically conductive path extends through the region and includes a second pad and a second trace, and wherein the first pad and the second pad are located at complementary positions within a geometric pad pattern, and the first trace and the second trace extend in complementary directions.

Example 12 may include the computer device of example 11 or any other example herein, wherein the first pad and the second pad are adjacently located within the geometric pad pattern.

Example 13 may include the computer device of example 11 or any other example herein, wherein the first pad and the second pad are located at a surface of the region, wherein the first electrically conductive path further includes a first via that extends through the region, wherein the first trace couples the first pad and the first via and extends in a first direction, wherein the second electrically conductive path further includes a second via that extends through the region, and wherein the second trace couples the second pad and the second via and extends in a second direction that is different from the first direction.

Example 14 may include the computer device of example 11 or any other example herein, wherein the second direction is approximately perpendicular to the first direction.

Example 15 may include the computer device of example 11 or any other example herein, wherein the geometric pad pattern is a square pad pattern, and wherein the first pad and the second pad are located at adjacent positions within the square pad pattern.

Example 16 may include the computer device of example 11 or any other example herein, wherein the geometric pad pattern is a trapezoidal pad pattern, and wherein the first pad and the second pad are located at adjacent positions within the trapezoidal pad pattern.

Example 17 may include the computer device of example 11 or any other example herein, wherein the first pad and the second pad are included within a ball grid array formed at a surface of the region, and wherein the processor is coupled to the electrical routing component via the ball grid array.

Example 18 may include the computer device of example 11 or any other example herein, wherein the region is a layer of the electrical routing component.

Example 19 may include the computer device of example 11 or any other example herein, wherein the computer device is a server, and further comprises a printed circuit board (PCB), wherein the electrical routing component is an integrated circuit substrate that couples the processor and the PCB.

Example 20 may include an electrical routing component for a computer device, comprising a first group of pads for conduction of a first plurality of differential pairs, the first group of pads located at a surface of the electrical routing component, wherein the first group of pads includes a first pair of pads to conduct signals of a first differential pair, and a second pair of pads to conduct signals of a second differential pair, wherein the second pair of pads is oriented in a different direction from the first pair of pads, a second group of pads for conduction of a second plurality of differential pairs, the second group of pads located at the surface of the electrical routing component, and a third group of pads to couple to ground, wherein the third group of pads are located between the first group of pads and the second group of pads and isolates the first group of pads and the second group of pads.

Example 21 may include the electrical routing component of example 20 or any other example herein, wherein the third group of pads includes a line of pads that separates the first group of pads from the second group of pads.

Example 22 may include the electrical routing component of example 20 or any other example herein, wherein the first group of pads further includes a third pair of pads to conduct signals of a third differential pair, wherein the third pair of pads is orientated in a different direction from the first pair of pads and the second pair of pads, and wherein the third group of pads surround the first group of pads.

Example 23 may include an electrical routing component for a computer device, comprising a first via to conduct a first signal of a differential pair, a second via to conduct a second signal of the differential pair, and a trace formed of conductive material and routed adjacent to the first via and the second via, wherein an area of a first portion of the trace located adjacent to the first via is greater than an area of a second portion of the trace located adjacent to the second via.

Example 24 may include the electrical routing component of example 23 or any other example herein, wherein a width of the first portion of the trace is greater than a width of the second portion of the trace.

Example 25 may include the electrical routing component of example 20 or any other example herein, wherein the area of the first portion of the trace is selected to have an electromagnetic coupling to the first via that is approximately equal to an electromagnetic coupling of the second portion of the trace to the second via.

It will be apparent to those skilled in the art that various modifications and variations can be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

What is claimed is:

1. An apparatus for a computer device, comprising:
a first electrically conductive path that extends through a region of the apparatus, wherein the first electrically conductive path includes:
a first pad located at a surface of the region;
a first via that extends through the region; and
a first trace that couples the first pad and the first via, wherein the first trace extends in a first direction; and
a second electrically conductive path that extends through the region, wherein the second electrically conductive path includes:
a second pad located at the surface of the region and adjacent to the first pad;
a second via that extends through the region; and
a second trace that couples the second pad and the second via, wherein the second trace extends in a second direction that is different from the first direction.

2. The apparatus of claim 1, wherein the second direction is approximately perpendicular to the first direction.

3. The apparatus of claim 1, wherein the first pad and the second pad are located within a square pad pattern, and wherein the first pad and the second pad are located at adjacent positions within the square pad pattern.

4. The apparatus of claim 1, wherein the first pad and the second pad are located within a trapezoidal pad pattern, and wherein the first pad and the second pad are located at adjacent positions within the trapezoidal pad pattern.

5. The apparatus of claim 1, wherein the first pad and the second pad are included within a ball grid array formed at the surface of the region.

6. The apparatus of claim 1, wherein the first trace and the second trace extend along the surface of the region.

7. The apparatus of claim 1, wherein the region is a layer of the apparatus.

8. The apparatus of claim 1, wherein the first electrically conductive path is to conduct a signal of a first differential pair, and wherein the second electrically conductive path is to conduct a signal of a second differential pair.

9. The apparatus of claim 1, wherein the apparatus is a printed circuit board.

10. The apparatus of claim 1, wherein the apparatus is an integrated circuit substrate.

11. A computer device, comprising:
a processor; and
an electrical routing component coupled to the processor, the electrical routing component to conduct signals of differential pairs for the processor, wherein the electrical routing component includes:
a first electrically conductive path to conduct a signal of a first differential pair, wherein the first electrically conductive path extends through a region and includes a first pad and a first trace; and
a second electrically conductive path to conduct a signal of a second differential pair, wherein the second electrically conductive path extends through the region and includes a second pad and a second trace, and wherein the first pad and the second pad are located at complementary positions within a geometric pad pattern, and the first trace and the second trace extend in complementary directions.

12. The computer device of claim 11, wherein the first pad and the second pad are adjacently located within the geometric pad pattern.

13. The computer device of claim 11, wherein the first pad and the second pad are located at a surface of the region, wherein the first electrically conductive path further includes a first via that extends through the region, wherein the first trace couples the first pad and the first via and extends in a first direction, wherein the second electrically conductive path further includes a second via that extends through the region, and wherein the second trace couples the second pad and the second via and extends in a second direction that is different from the first direction.

14. The computer device of claim 13, wherein the second direction is approximately perpendicular to the first direction.

15. The computer device of claim 11, wherein the geometric pad pattern is a square pad pattern, and wherein the first pad and the second pad are located at adjacent positions within the square pad pattern.

16. The computer device of claim 11, wherein the geometric pad pattern is a trapezoidal pad pattern, and wherein the first pad and the second pad are located at adjacent positions within the trapezoidal pad pattern.

17. The computer device of claim 11, wherein the first pad and the second pad are included within a ball grid array formed at a surface of the region, and wherein the processor is coupled to the electrical routing component via the ball grid array.

18. The computer device of claim 11, wherein the region is a layer of the electrical routing component.

19. The computer device of claim 11, wherein the computer device is a server, and further comprises a printed circuit board (PCB), wherein the electrical routing component is an integrated circuit substrate that couples the processor and the PCB.

20. An electrical routing component for a computer device, comprising:
a first group of pads for conduction of a first plurality of differential pairs, the first group of pads located at a surface of the electrical routing component, wherein the first group of pads includes:
a first pair of pads to conduct signals of a first differential pair; and
a second pair of pads to conduct signals of a second differential pair, wherein the second pair of pads is oriented in a different direction from the first pair of pads;
a second group of pads for conduction of a second plurality of differential pairs, the second group of pads located at the surface of the electrical routing component; and
a third group of pads to couple to ground, wherein the third group of pads are located between the first group of pads and the second group of pads and isolates the first group of pads and the second group of pads.

21. The electrical routing component of claim 20, wherein the third group of pads includes a line of pads that separates the first group of pads from the second group of pads.

22. The electrical routing component of claim 20, wherein the first group of pads further includes a third pair of pads to conduct signals of a third differential pair, wherein the third pair of pads is orientated in a different direction from the first pair of pads and the second pair of pads, and wherein the third group of pads surround the first group of pads.

23. An electrical routing component for a computer device, comprising:
a first via to conduct a first signal of a differential pair;
a second via to conduct a second signal of the differential pair; and
a trace formed of conductive material and routed adjacent to the first via and the second via, wherein an area of a first portion of the trace located adjacent to the first via is greater than an area of a second portion of the trace located adjacent to the second via.

24. The electrical routing component of claim 23, wherein a width of the first portion of the trace is greater than a width of the second portion of the trace.

25. The electrical routing component of claim 23, wherein the area of the first portion of the trace is selected to have an electromagnetic coupling to the first via that is approximately equal to an electromagnetic coupling of the second portion of the trace to the second via.
